(19) United States
(12) Patent Application Publication
(10) Pub. No.: US 2025/0062303 A1
(43) Pub. Date: Feb. 20, 2025

(54) SEMICONDUCTOR PACKAGES

(71) Applicant: Samsung Electronics Co., Ltd., Suwon-si (KR)

(72) Inventors: Joonho Jun, Suwon-si (KR); Duksung Kim, Suwon-si (KR); Gyesik Oh, Suwon-si (KR); Minwoo Lee, Suwon-si (KR); Wangyong Im, Suwon-si (KR); Byoungkon Jo, Suwon-si (KR)

(21) Appl. No.: 18/663,211

(22) Filed: May 14, 2024

(30) Foreign Application Priority Data
Aug. 16, 2023 (KR) 10-2023-0107139

(51) Int. Cl. H01L 25/18; H01L 23/00; H01L 23/31; H01L 23/48

(52) U.S. Cl. CPC H01L 25/18; H01L 23/3121; H01L 23/481; H01L 24/16; H01L 24/08; H01L 2224/08146; H01L 2224/08238; H01L 2224/16145; H01L 2224/16225; H01L 2225/06513; H01L 2225/06517; H01L 2225/06562; H01L 2924/1815

(57) ABSTRACT

A semiconductor package may include a package substrate; a plurality of upper dies on an upper side of the package substrate and arranged so as not to overlap each other vertically; a plurality of electrical connection structures between the plurality of upper dies and the package substrate and electrically connected to the package substrate; a lower die on the package substrate and arranged so as not to vertically overlap with the plurality of electrical connection structures; and a plurality of overlapped electrical connection structures arranged between the plurality of upper dies and an upper surface of the lower die and electrically connected to the upper surface of the lower die. Each of the plurality of upper dies may include a plurality of memory dies that overlap each other vertically.

### CROSS-REFERENCE TO RELATED APPLICATION

This application claims the benefit under 35 U.S.C. § 119(a) of Korean Patent Application No. 10-2023-0107139, filed on Aug. 16, 2023, in the Korean Intellectual Property Office, and the entire contents of the above-identified application are incorporated by reference herein for all purposes.

### BACKGROUND

The present inventive concept relates to semiconductor packages.

Recently, there has been a demand for increased performance and/or increased capacity of semiconductor packages that are to be installed in electronic devices. Accordingly, semiconductor packages containing a plurality of dies are under development, and a data transmission speed of signals transmitted and received between a plurality of dies is gradually increasing. For example, semiconductor packages may be implemented with high bandwidth memory (HBM), and it may be desirable that the size (e.g., planar size) of the semiconductor packages be limited or reduced.

### SUMMARY

Some aspects of the present disclosure provide semiconductor packages that may implement or exhibit improved performance and/or increased capacity, and may do so in a relatively efficient manner.

According to some embodiments, a semiconductor package may include a package substrate; a plurality of upper dies on an upper side of the package substrate, each upper die arranged so as not to overlap vertically with other upper dies of the plurality of upper dies, and each upper die including a plurality of vertically overlapping memory dies; a plurality of electrical connection structures between the plurality of upper dies and the package substrate, the plurality of electrical connection structures electrically connected to the package substrate; a lower die on the package substrate and arranged so as not to vertically overlap with the plurality of electrical connection structures; and a plurality of overlapped electrical connection structures arranged between the plurality of upper dies and an upper surface of the lower die, the plurality of overlapped electrical connection structures electrically connected to the upper surface of the lower die.

According to some embodiments, a semiconductor package may include a package substrate; a plurality of upper dies above the package substrate each upper die arranged so as not to overlap vertically with others of the plurality of upper dies; a plurality of electrical connection structures between the plurality of upper dies and the package substrate, the plurality of electrical connection structures electrically connected to the package substrate; and a lower die on the package substrate and arranged so as not to vertically overlap with the plurality of electrical connection structures. Each of the plurality of upper dies may partially overlap the lower die vertically, and the plurality of electrical connection structures may be asymmetrically arranged with respect to respective centers of the plurality of upper dies.

According to some embodiments, a semiconductor package may include a package substrate; at least one upper die on the package substrate; a plurality of electrical connection structures between the at least one upper die and the package substrate, the plurality of electrical connection structures electrically connected to the package substrate; a lower die on the package substrate and arranged so as not to vertically overlap with the plurality of electrical connection structures; an encapsulant that seals the plurality of electrical connection structures and the lower die; and at least one buffer die electrically connected between and to the at least one upper die and the plurality of electrical connection structures. A lower surface of the buffer die may be in direct contact with the encapsulant.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a perspective view illustrating a semiconductor package according to some embodiments;

FIG. 1B is a cross-sectional view illustrating a semiconductor package according to some embodiments;

FIGS. 2A, 2B, and 2C are cross-sectional views illustrating a method of manufacturing a semiconductor package according to some embodiments;

FIGS. 3A, 3B, and 3C are perspective views illustrating a semiconductor package according to some embodiments;

FIGS. 4A and 4B are perspective views illustrating a semiconductor package according to some embodiments;

FIGS. 5A, 5B, 5C, and 5D are plan views illustrating a semiconductor package according to some embodiments;

FIGS. 6A, 6B, 6C, and 6D are cross-sectional views illustrating a semiconductor package according to some embodiments;

FIGS. 7A and 7B are cross-sectional views illustrating a semiconductor package according to some embodiments;

FIG. 8A is a block diagram illustrating the connection between dies of a semiconductor package according to some embodiments; and

FIG. 8B is a block diagram illustrating a memory die of each of a plurality of upper dies of a semiconductor package according to some embodiments.

### DETAILED DESCRIPTION

Hereinafter, some examples of embodiments will be described with reference to the accompanying drawings.

The detailed description of the present inventive concept described below refers to the accompanying drawings, which illustrate by way of example specific embodiments in which the present inventive concept may be practiced. These embodiments are described in sufficient detail to enable those skilled in the art to practice the invention. It should be understood that the various embodiments are different from one another but are not necessarily mutually exclusive. For example, specific shapes, structures and characteristics described herein with respect to one embodiment may be implemented in other embodiments without departing from the spirit and scope of the invention. Additionally, it should be understood that the location or arrangement of individual components within each disclosed embodiment may be changed without departing from the spirit and scope of the invention. Accordingly, the detailed description below is not intended to be taken in a limiting sense, and the scope of the present inventive concept is limited only by the appended claims, together with all equivalents asserted in those claims. Similar reference numbers in the drawings refer to identical or similar functions across various aspects.

Below, in order to enable those skilled in the art to easily practice the present inventive concept, embodiments will be described in detail with reference to the attached drawings.

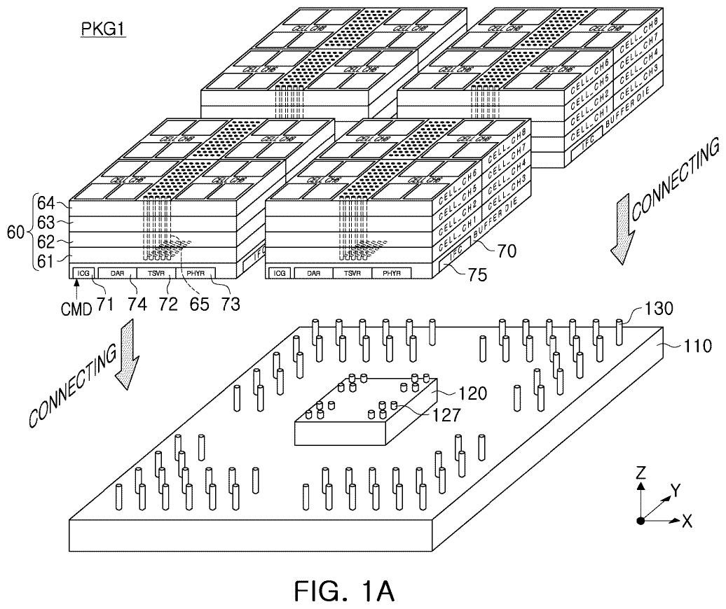

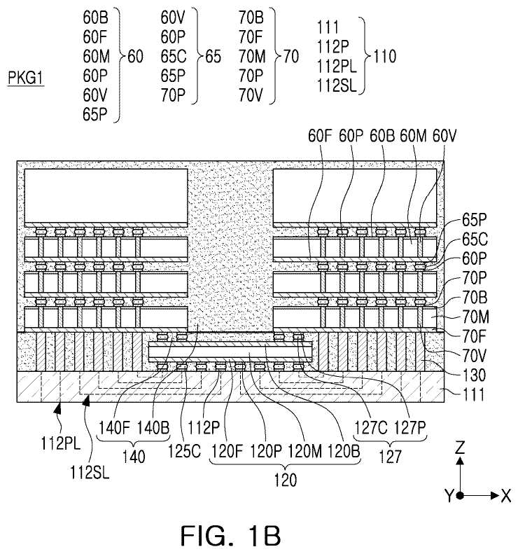

FIG. 1A is a perspective view illustrating a plurality of upper dies 60 of a semiconductor package (PKG1) connected to the upper end of a plurality of electrical connection structures 130 according to some embodiments, and FIG. 1B is a cross-sectional view of the semiconductor package PKG1 of FIG. 1A when the semiconductor package PKG1 is cut along the XZ plane from the Y-direction perspective. FIG. 1B illustrates one of the memory dies 61, 62, 63, and 64 of FIG. 1A omitted, and FIG. 1A illustrates the encapsulant 140 of FIG. 1B omitted.

Referring to FIGS. 1A and 1B, a semiconductor package (PKG1) according to an example embodiment may include a package substrate 110, a plurality of upper dies 60, a plurality of electrical connection structures 130, and a lower die 120, and may further include buffer dies 70 and/or a plurality of overlapped electrical connection structures 127.

The package substrate 110 may have a structure in which at least one wiring layer and at least one insulating layer 111 are alternately stacked, and may be a printed circuit board, but the present disclosure is not limited thereto. The at least one wiring layer may include signal lines 112SL and/or power lines 112PL, and may include a redistribution line depending on design. Further, depending on the design, the at least one wiring layer and the signal lines 112SL and/or power lines 112PL thereof may protrude on the upper and lower surfaces of the package substrate 110, and may include copper (Cu), aluminum (Al), silver (Ag), tin (Sn), gold (Au), nickel (Ni), lead (Pb), and/or titanium (Ti), or an alloy of at least one thereof. The at least one insulating layer 111 may include prepreg, but the present disclosure is not limited thereto. For example, the insulating layer 111 may also include at least one of photosensitive insulating materials such as Photo Imageable Dielectric (PID) resin, build-up films such as Ajinomoto Build-up Film (ABF), thermosetting resins such as epoxy resins, thermoplastic resins such as polyimide, resins mixed with inorganic fillers, FR-4 (Flame Retardant) and Bismalcimide Triazine (BT).

The lower die 120 may be on the package substrate 110, and the plurality of upper dies 60 and buffer dies 70 may be on the package substrate 110. The lower die 120 may include a semiconductor substrate 120M, circuit layers 120F and 120B, and pads 120P. Each of the plurality of upper dies 60 may include a semiconductor substrate 60M, circuit layers 60F and 60B, pads 60P and 65P, and through-vias 60V, and each of the buffer dies 70 may include a semiconductor substrate 70M, circuit layers 70F and 70B, pads 70P, and through-vias 70V.

For example, each of the semiconductor substrates 60M, 70M and 120M may include a semiconductor element such as silicon and/or germanium, or compound semiconductors such as silicon carbide (SiC), gallium arsenide (GaAs), indium arsenide (InAs), and indium phosphide (InP), and each of the semiconductor substrates 60M, 70M and 120M may be implemented or based on a wafer. The semiconductor substrates 60M and 70M may have a polygonal structure through which through-vias 60V and 70V pass, and the semiconductor substrate 120M may have a polygonal structure in which through-vias do not penetrate. Each of the circuit layers 60F, 60B, 70F, 70B, 120F and 120B may include insulating layers (e.g., including silicon oxide (SiO), silicon nitride (SIN), silicon oxynitride (SiON), silicon oxycarbide (SiOC), and/or silicon carbonitride (SiCN), or a combination of two or more thereof), and wiring, and may be implemented as front end of line (FEOL) or back end of line (BEOL). For example, the wiring and pads (60P, 65P, 70P, 120P) and through-vias (60V, 70V) may include aluminum (Al), gold (Au), cobalt (Co), copper (Cu), nickel (Ni), lead (Pb), tantalum (Ta), tellurium (Te), titanium (Ti), tungsten (W) or combinations thereof.

The device layer of each die (e.g., the upper dies 60, the buffer dies 70, and the lower die 120) may be between the semiconductor substrate (60M, 70M, 120M) and the circuit layer (60F, 70F, 120F) thereof, and may include transistors constituting an integrated circuit. For example, the transistors that make up the integrated circuit in each device layer may include Planar Metal Oxide Semiconductor FET (MOSFET), FinFET in which active area has a fin structure, Multi Bridge Channel FET (MBCFET™) or Gate-All-Around transistors including a plurality of channels stacked vertically on the active area, or Vertical FET (VFET), but the present inventive concepts are not limited thereto. The integrated circuit may be a micro-processor, Central Processing Unit (CPU), Graphics Processing Unit (GPU), Field Programmable Gate Array (FPGA), Application Processor (AP), Digital Signal Processor (DSP), other digital processor or signal processor, cryptographic processor, controller, or application specific integrated circuit (ASIC), or the like, and/or may also include volatile memory devices such as DRAM, static RAM (SRAM), or the like, and/or non-volatile memory devices such as PRAM, MRAM, ReRAM, and flash memory devices, or the like.

The semiconductor substrates 60M, 70M, and 120M may support the device layer. The circuit layers 60F, 70F, and 120F may provide electrical connection paths between the device layer and the pads 60P, 65P, 70P, and 120P, and the circuit layers 60F, 70F, and 12OF may support the pads 60P, 65P, 70P and 120P. The pads 60P, 65P, 70P, and 120P may provide electrical connection paths between the circuit layers 60F, 70F, and 120F and a device or component outside the die. Through-vias 60V and 70V may provide electrical connection paths upward from the device layer, and the circuit layers 60B and 70B may provide upward electrical connection paths in the through-vias 60V and 70V.

The design of the device layer of each die may be influenced by the through-vias (60V, 70V) that provide electrical connection paths to the device layer. Therefore, as compared to the design of the device layer of a die containing through-vias (60V, 70V), the design of the device layer of a die with no or few through-vias (60V, 70V) may be said to be freer or more free. The freer the design of the device layer, the higher the design efficiency of the device layer may be. As the design efficiency of the device layer increases, the performance relative to the die size may be higher.

Since the lower die 120 may not include through-vias or may include limited through-vias only near the corners of the lower die 120, the design freedom/efficiency of the lower die 120 may be increased. However, if the lower die 120 does not include or barely includes through-vias, since the lower die 120 may provide electrical connection paths only on one of the upper and lower surfaces of the lower die 120, the degree of freedom in designing the arrangement/connection relationship between the lower die 120 and the plurality of upper dies 60 may be further reduced.

The plurality of upper dies 60 may not overlap each other vertically, and each of the plurality of upper dies 60 may include a plurality of memory dies 61, 62, 63, and 64 overlapping each other vertically. For example, the integrated circuit of the device layer of the plurality of memory dies 61, 62, 63 and 64 may include volatile memory devices such as DRAM, SRAM (static RAM), and the like, or non-volatile memory devices such as PRAM, MRAM, ReRAM, and flash memory devices. For example, the plurality of memory dies 61, 62, 63, and 64 include a plurality of channels having independent interfaces and may be a memory device in the form of HBM (high bandwidth memory) with increased bandwidth.

As the number of memory dies 61, 62, 63, and 64 increases, the performance (e.g., bandwidth, storage capacity) of the memory device may increase. The higher the degree of design freedom in the arrangement/connection relationship between the lower die 120 and the plurality of upper dies 60, the number (and/or total size) of the plurality of memory dies 61, 62, 63, and 64 may be further increased compared to the size of the semiconductor package PKG1.

The plurality of electrical connection structures 130 may not overlap the lower die 120 vertically, and at least portions of the plurality of electrical connection structures 130 may be used as signal paths between the lower die 120 and the plurality of memory dies 61, 62, 63, and 64. Accordingly, the degree of freedom in designing the arrangement/connection relationship between the lower die 120 and the plurality of upper dies 60 may be increased. The plurality of electrical connection structures 130 may be arranged to overlap vertically with the plurality of upper dies 60 and the package substrate 110, and may be electrically connected between the plurality of upper dies 60 and the package substrate 110. The plurality of electrical connection structures 130 may be electrically connected to the plurality of upper dies 60 through the buffer dies 70, and at least a portion of the plurality of electrical connection structures 130 may be electrically connected to the lower die 120 through the package substrate 110.

Therefore, the semiconductor package PKG1 according to some embodiments may increase (e.g., may increase efficiently) the number of the plurality of memory dies 61, 62, 63, and 64 (e.g., 12, 16), and the performance (e.g., bandwidth, memory capacity) of the memory device may be increased (e.g., may be increased efficiently). In addition, the semiconductor package PKG1 may exclude or almost exclude through-vias from the lower die 120, and the design freedom/efficiency of the lower die 120 may be increased, and the performance (e.g. speed) of the lower die 120 may also be increased (e.g., may also be increased efficiently).

The plurality of overlapping electrical connection structures 127 may be between the plurality of upper dies 60 and the upper surface of the lower die 120 and electrically connected to the upper surface of the lower die 120, and may be used as signal paths between the plurality of upper dies 60 and lower die 120. The plurality of overlapped electrical connection structures 127 may overlap each of the plurality of upper dies 60 vertically, and may thus be arranged adjacent to each corner of the upper surface of the lower die 120. The vertical length of the plurality of overlapping electrical connection structures 127 may be shorter than the vertical length of the plurality of electrical connection structures 130.

The signal paths of the plurality of overlapping electrical connection structures 127 and the signal paths of the plurality of electrical connection structures 130 may be parallel to each other, and the length of the signal paths of the plurality of overlapping electrical connection structures 127 may be shorter than the length of the signal paths of the plurality of electrical connection structures 130. Accordingly, the signal paths between the plurality of upper dies 60 and the lower die 120 may include both relatively long signal paths (e.g., by way of the plurality of electrical connection structures 130) and relatively short signal paths (e.g., by way of the plurality of overlapping electrical connection structures 127), and interface design flexibility/optimality between the plurality of upper dies 60 and the lower die 120 may be further increased. In addition, due to the presence of the plurality of overlapping electrical connection structures 127, it may be advantageous for the plurality of upper dies 60 to be placed in closer contact with each other, and performance (e.g., memory capacity, interface speed) relative to the unit size of the plurality of upper dies 60 may be further improved.

For example, the plurality of overlapped electrical connection structures 127 may include overlap bumps 127C and overlap pads 127P. First ones of the overlap pads 127P may be on the upper surface of the lower die 120, and the remainder of the overlap pads 127P (e.g., second ones of the overlap pads 127P) may be on top of the first ones of the overlap pads 127P. The overlap bumps 127C may be connected and fixed between the first ones and the remaining ones of the overlap pads 127P. For example, the overlap pads 127P may be implemented in substantially the same manner (e.g., the same material, the same shape) as the pads 60P, 65P, 70P, and 120P, and the overlap bumps 127C may be formed of a conductive material (e.g., lead (Pb), tin (Sn), alloys thereof (Sn-Ag-Cu)) or solder having a lower melting point than the melting point of the overlap pads 127P. The overlap bumps 127C may be connected and fixed to the overlap pads 127P through a thermal compression bonding (TCB) process or a reflow process.

The plurality of electrical connection structures 130 may be in the form of metal pillars extending up and down (e.g., in the form of a Cu post), but the present disclosure is not limited thereto. For example, the plurality of electrical connection structures 130 may be implemented as bumps or solder balls. In some embodiments, the plurality of electrical connection structures 130 that are implemented as bumps or solder balls may be implemented larger in a similar manner to the overlap bumps 127C.

Bumps 125C may be connected and fixed between the pad 120P of the lower die 120 and the pad 112P of the package substrate 110, and the lower die 120 may be mounted on the package substrate 110. Bumps 65C may be connected and fixed between the pads 65P of the plurality of upper dies 60 and the pads 70P of the plurality of buffer dies 70, or may be connected and fixed between the pads 60P and 65P of the plurality of upper dies 60. For example, the bumps 65C and 125C may include a conductive material (e.g. lead (Pb), tin (Sn), alloys thereof (Sn-Ag-Cu)) having a lower melting point than the melting point of the pads (60P, 65P, 70P, 112P, 120P), or solder, and the bumps 65C and 125C may be connected and fixed to the pads (60P, 65P, 70P, 112P, 120P) through a thermal compression bonding (TCB) process or a reflow process.

The plurality of electrical connection structures 130 may be arranged to surround the lower die 120 and thus may be arranged along one or more edges of the upper surface of the package substrate 110. Accordingly, the plurality of upper dies 60 may also be arranged along the one or more edges of the upper surface of the package substrate 110. Since the shape of each of the plurality of upper dies 60 may be close to a rectangular parallelepiped, the plurality of upper dies 60 may be at least four upper dies 60 arranged so as not to overlap each other vertically. Accordingly, the plurality of memory dies 61, 62, 63, and 64 may be arranged in a balanced manner from a three-dimensional perspective. The number of memory dies 61, 62, 63, and 64 may be increased more efficiently. For example, the ratio of the upper and lower surfaces (X-Y plane) area and the length in the Z direction of the combination structure of the plurality of memory dies 61, 62, 63, and 64 and the plurality of memory dies 61, 62, 63, and 64, respectively. Since the ratio of the area of the upper and lower surfaces (X-Y plane) and the length in the Z direction may be similar, the plurality of memory dies 61, 62, 63, and 64 may be arranged in a balanced manner from a three-dimensional perspective. Due to the balanced arrangement, secondary effects due to an increase in the number of memory dies 61, 62, 63, and 64 may also be reduced. Accordingly, the number of memory dies 61, 62, 63, and 64 may be increased more efficiently.

The Z-direction length (or vertical direction length) of the plurality of electrical connection structures 130 may be greater than or equal to the Z-direction thickness (or vertical direction thickness) of the lower die 120. Accordingly, the lower surface of the plurality of buffer dies 70 (or, if there are no buffer dies 70, the lower surface of the lowermost memory die 61 of each upper die 60) may be located at a level no lower than the upper surface of the lower die 120. The lower surface of each of the plurality of buffer dies 70 may be coplanar with or above the upper surface of the lower die 120, relative to an upper surface of the package substrate 110. Accordingly, each of the at least four upper dies 60 may more easily use the space above the lower die 120, and the overall size of the at least four upper dies 60 may be larger. As the overall size of the at least four upper dies 60 increases, the overall performance (e.g., bandwidth, storage capacity) of the at least four upper dies 60 may be further improved. Alternatively, the horizontal size of the semiconductor package PKG1 may be reduced in an efficient manner.

Since each of the plurality of upper dies 60 may use the space above the lower die 120, each of the plurality of upper dies 60 may partially overlap the lower die 120 vertically. For example, since each of the at least four upper dies 60 may use the space above the lower die 120, each of the at least four upper dies 60 may overlap a respective one of each of the four corners of the lower die 120 vertically. Accordingly, the performance (e.g. bandwidth, memory capacity) compared to the horizontal size of the semiconductor package (PKG1) may be improved in an efficient manner.

Since the plurality of electrical connection structures 130 may extend up and down and may bypass the lower die 120, the plurality of electrical connection structures 130 may be arranged asymmetrically with respect to the center of each of the plurality of upper dies 60. For example, among the plurality of upper dies 60, the plurality of electrical connection structures 130 connected to the upper die 60 on a first side of the lower die 120 in a horizontal direction (e.g., the left side in the cross-sectional view of FIG. 1B) may be arranged to be biased to the first side with respect to the center of the upper die 60 on the first side of the lower die 120 in the horizontal direction, and among the plurality of upper dies 60, the plurality of electrical connection structures 130 connected to the upper die 60 on a second side of the lower die 120 in the horizontal direction (e.g., the right side in the cross-sectional view of FIG. 1B) may be arranged to be biased to the second side with respect to the center of the upper die on the second side of the lower die 120 in the horizontal direction.

Conductive materials (e.g., metal materials, plating materials, conductive paste) included in the plurality of electrical connection structures 130 for electrical connection may have relatively strong overall strength. Accordingly, the plurality of electrical connection structures 130 may provide force to physically support the plurality of upper dies 60. The asymmetrical arrangement of the plurality of electrical connection structures 130 may cause a force that tilts the plurality of upper dies 60 in one horizontal direction. The force with which the lower die 120 physically supports the plurality of upper dies 60 may cancel out the tilting force. Therefore, the semiconductor package PKG1 according to some embodiments may be advantageous to support (in a stable manner) the plurality of upper dies 60 and increase reliability even if the number of memory dies 61, 62, 63, and 64 increases.

Portions (e.g., first ones, first portions) of the plurality of electrical connection structures 130 may be connected to the signal wires 112SL of the package substrate 110, and may be electrically connected to the lower die 120. Other portions (e.g., second ones, second portions) of the plurality of electrical connection structures 130 may be connected to the power wires 112PL of the package substrate 110, and may be used as power supply paths for the plurality of upper dies 60 from an outside source or component providing power to the semiconductor package PKG1. Accordingly, the lower die 120 may not include power supply paths for the plurality of upper dies 60, and the design freedom and efficiency of the lower die 120 may be further improved.

Referring to FIG. 1B, the semiconductor package PKG1 according to some example embodiments may further include at least one of upper and lower electrical connection paths 65 and an encapsulant 140.

The upper and lower electrical connection paths 65 may be implemented to pass vertically through a plurality of memory dies 61, 62, 63, and 64 and/or a plurality of buffer dies 70, and may include at least portions of the bumps 65C, pads 60P, 65P, and 70P, and through-vias 60V. The horizontal arrangement positions of the upper and lower electrical connection paths 65 in FIG. 1A may vary depending on the design.

The encapsulant 140 may include a lower encapsulant 140F and/or an upper encapsulant 140B. The lower encapsulant 140F may seal the plurality of electrical connection structures 130 and the lower die 120, and the upper encapsulant 140B may seal the plurality of upper dies 60. For example, the encapsulant 140 may contain a molding material such as Epoxy Molding Compound (EMC), but the present disclosure is not limited thereto, and may also contain an insulating material that may have similar protective properties or high ductility as the molding material. For example, the insulating material may be a build-up film (e.g., Ajinomoto Build-up Film (ABF)), a thermosetting resin such as epoxy resin, or a thermoplastic resin such as polyimide. The insulating material of the insulating layer 111 may be an insulating material in which inorganic fillers and/or glass fibers are added appropriately.

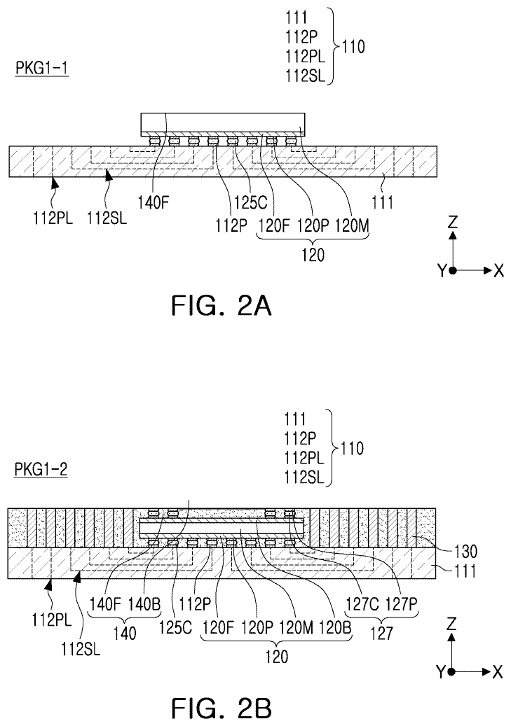

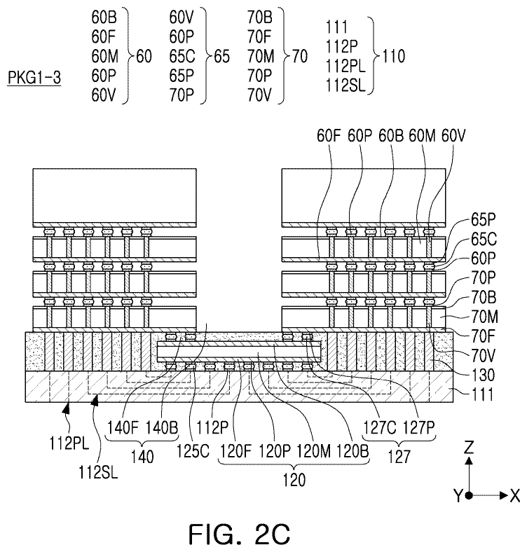

FIGS. 2A to 2C illustrate the semiconductor package PKG1 of FIGS. 1A and 1B being manufactured sequentially through a first state (PKG1-1), a second state (PKG1-2), and a third state (PKG1-3), but the manufacturing method of the semiconductor package PKG1 in FIGS. 1A and 1B is not limited to that illustrated in FIGS. 2A to 2C.

Referring to FIG. 2A, the first state (PKG1-1) of the semiconductor package according to some embodiments may include a structure in which the lower die 120 is mounted on the upper surface of the package substrate 110. Referring to FIG. 2B, the second state (PKG1-2) of the semiconductor package according to some embodiments may include a structure in which a plurality of electrical connection structures 130 are formed on the upper surface of the package substrate 110, and may include a structure in which the lower encapsulant 140F is filled or provided in the space or spaces not occupied by the plurality of electrical connection structures 130 and the lower die 120 on the upper surface of the package substrate 110.

The plurality of electrical connection structures 130 may be formed before the encapsulant 140F. For example, a photosensitive insulating layer having a thickness equal to the Z-direction extension length of the plurality of electrical connection structures 130 may be temporarily formed on the upper surface of the package substrate 110, through holes penetrating or extending through the photosensitive insulating layer may be formed, the plurality of electrical connection structures 130 may be formed by filling the surface or entire surface of each formed through hole with a conductive material (e.g., metal material, plating material, conductive paste), and the photosensitive insulating layer may be then removed and replaced with the encapsulant 140F.

Referring to FIG. 2C, the third state (PKG1-3) of the semiconductor package according to some embodiments may include a structure in which a plurality of upper dies 60 and/or a plurality of buffer dies 70 are arranged on the upper surface of the lower encapsulant 140F. Thereafter, the upper encapsulant 140B of FIG. 1B may be filled in the space not occupied by the plurality of upper dies 60 and the plurality of buffer dies 70 on the upper surface of the lower encapsulant 140F.

The lower surfaces of the plurality of buffer dies 70 may contact (e.g., may directly contact) the lower encapsulant 140F or the upper encapsulant 140B of FIG. 1B. If the plurality of buffer dies 70 are omitted, the lower surfaces of the plurality of upper dies 60 may contact (e.g., may directly contact) the lower encapsulant 140F or the upper encapsulant 140B of FIG. 1B. For example, there may be no bumps between the plurality of buffer dies 70 and the lower encapsulant 140F, and there may also be no non-conductive polymer that may be used with the bumps between the plurality of buffer dies 70 and the lower encapsulant 140F. Accordingly, the plurality of buffer dies 70 (and more particularly the lower surfaces and side surfaces thereof) may directly contact the lower encapsulant 140F and/or the upper encapsulant 140B of FIG. 1B. Accordingly, the upper surface of the lower encapsulant 140F may support the plurality of buffer dies 70 in a stable manner, and even if the number of the plurality of memory dies 61, 62, 63, and 64 increases, the plurality of upper dies 60 may be supported stably and in a manner that increases reliability advantageously.

Since the upper encapsulant 140B of FIG. 1B may be formed after the lower encapsulant 140F is formed, an interface may be formed between the lower surface of the upper encapsulant 140B and the upper surface of the lower encapsulant 140F. For example, the interface may be confirmed by at least one of a scanning electron microscope (SEM), an atomic force microscope (AFM), a transmission electron microscope (TEM), an optical microscope, and a surface profiler.

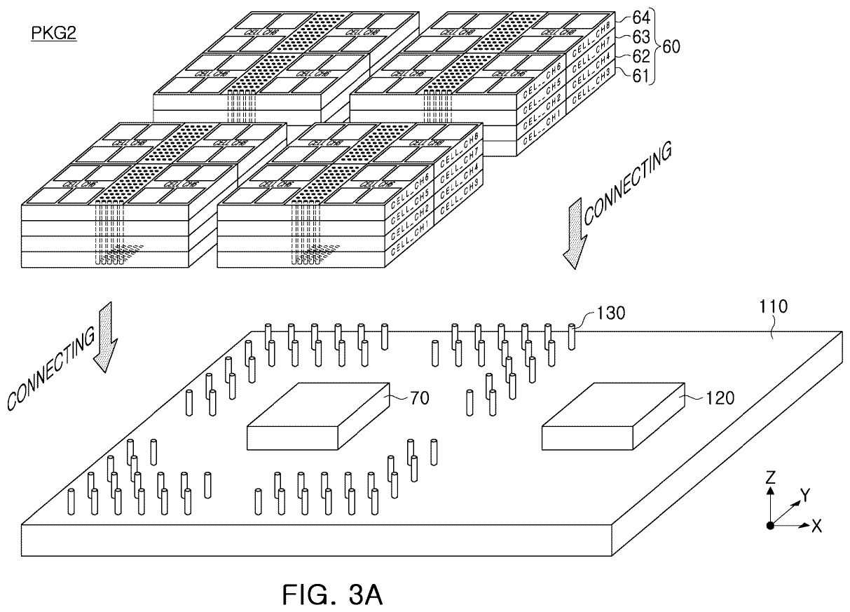

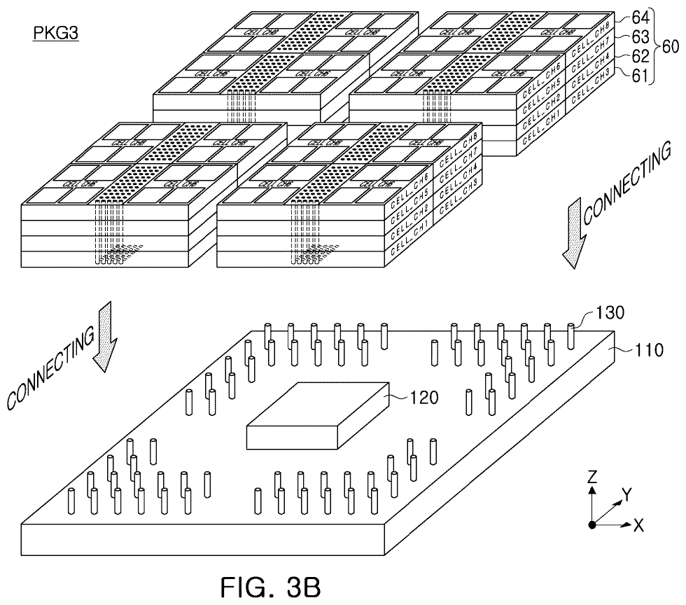

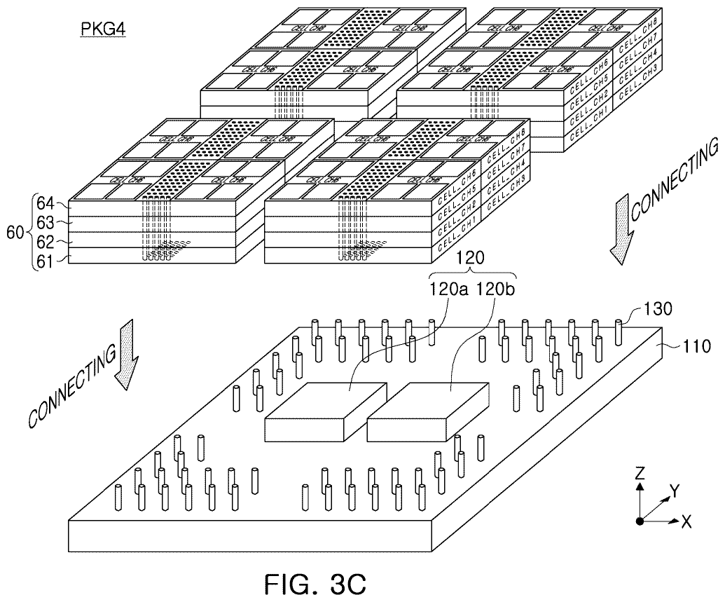

Referring to FIGS. 3A to 3C, semiconductor packages (PKG2, PKG3, PKG4) according to some embodiments may have structures in which the plurality of buffer dies 70 of FIG. 1A are omitted. For example, as seen in FIG. 3A, a single buffer die 70 may be provided in the semiconductor package PKG2, and the buffer die 70 of the semiconductor package PKG2 may be arranged in the space where the lower die 120 is located in the semiconductor package PKG1 of FIG. 1A. Thus, the singularly-provided buffer die 70 of the semiconductor package PKG2 may be regarded as a lower die. The buffer die 70 of the semiconductor package PKG2 may be surrounded by a plurality of electrical connection structures 130, and the plurality of upper dies 60 may partially overlap vertically. In some embodiments, as seen in FIG. 3A, the lower die 120 may be provided in the semiconductor package PKG2 in a horizontally-offset manner from the plurality of upper dies 60. In some embodiments, the buffer die 70 and the lower die 120 of the semiconductor package PKG2 may be electrically connected to each other through the package substrate 110. In some embodiments, as seen in FIG. 3B and the semiconductor package PKG3 thereof, a buffer die 70 may be completely omitted from the semiconductor package PKG3. As seen in FIG. 3C and the semiconductor package PKG4 thereof, the lower die 120 of the semiconductor package PKG4 may be divided into a plurality of lower dies 120a and 120b. The number of lower dies 120a and 120b is not limited to one or two.

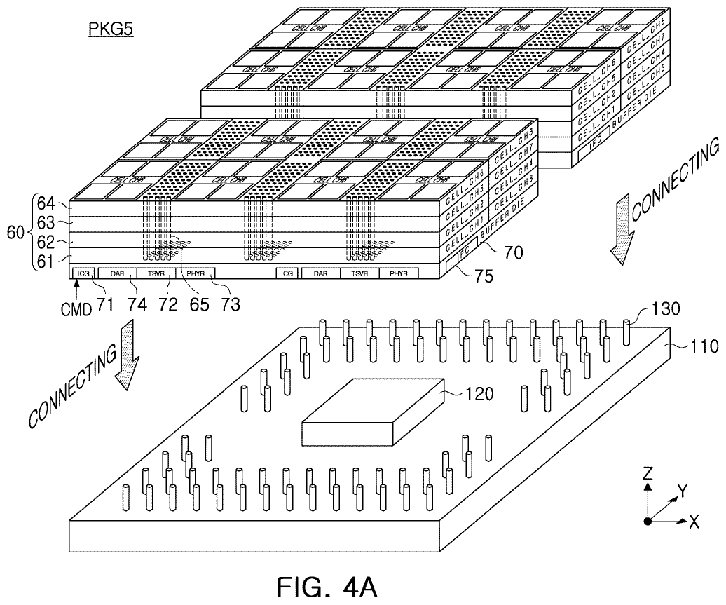

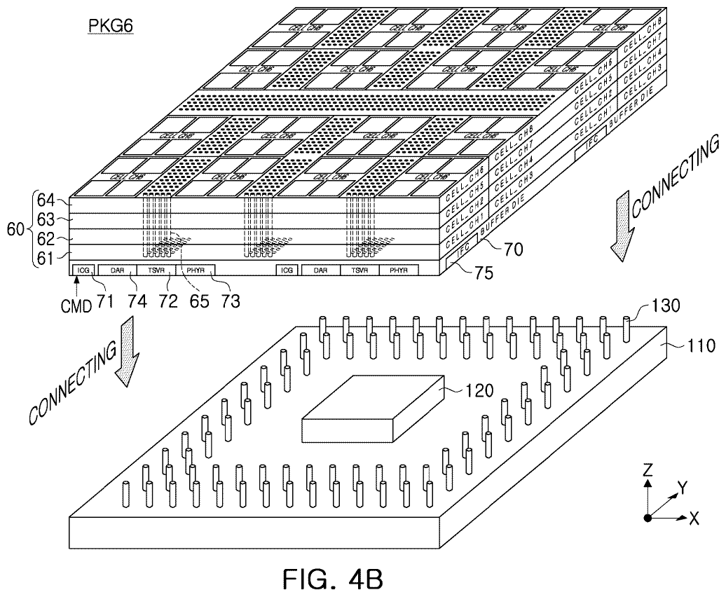

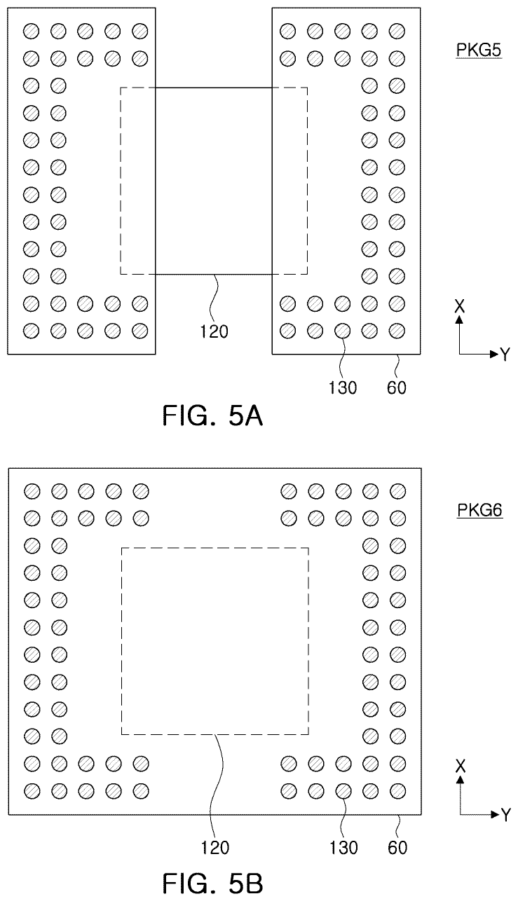

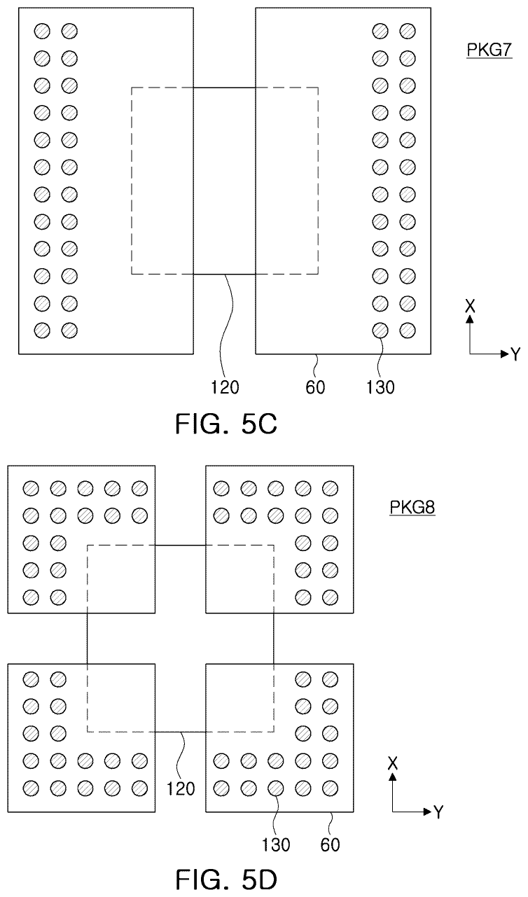

Referring to FIGS. 4A and 5A, in a semiconductor package (PKG5) according to some embodiments, the at least four upper dies 60 of FIG. 1A may have a structure in which the upper dies 60 are integrated into two upper dies 60. Accordingly, the plurality of electrical connection structures 130 may be arranged into two substantially U-shaped configurations, which may at least partially surround the lower die 120. Referring to FIGS. 4B and 5B, in the semiconductor package (PKG6) according to some embodiments, the at least four upper dies 60 of FIG. 1A may have a structure in which the upper dies integrated into one upper die 60. As seen in FIG. 5B, in the semiconductor package PKG6 the plurality of electrical connection structures 130 may be arranged into two substantially U-shaped configurations, which may at least partially surround the lower die 120.

Referring to FIG. 5C, the plurality of electrical connection structures 130 of a semiconductor package (PKG7) according to some embodiments may be arranged in two I-shaped configurations. Referring to FIG. 5D, the arrangement of the plurality of electrical connection structures 130 of the semiconductor package (PKG8) according to some embodiments may be in four L-shaped configurations.

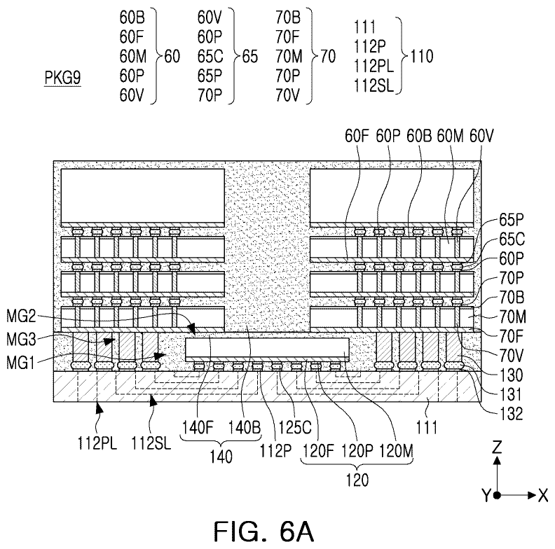

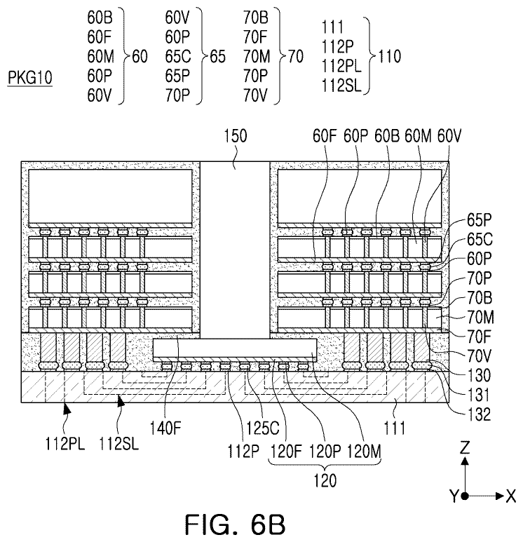

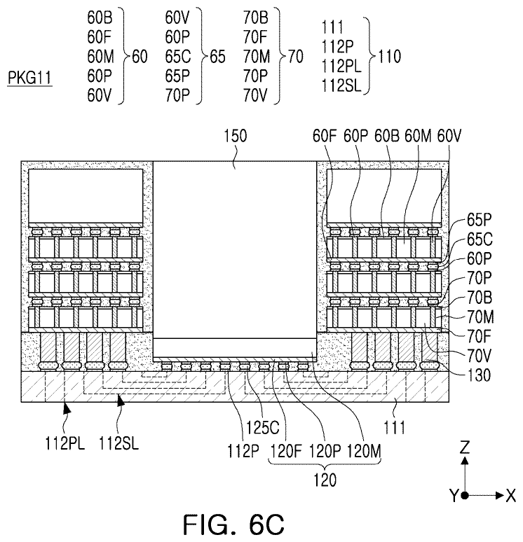

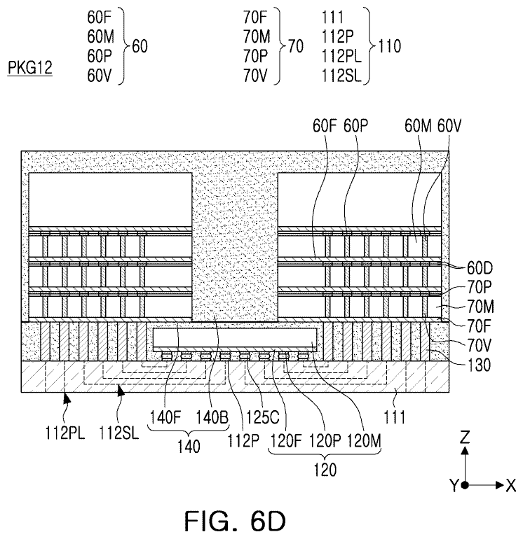

Referring to FIG. 6A, a plurality of electrical connection structures 130, 131, and 132 of a semiconductor package (PKG9) according to some embodiments may have a structure in which a first part 130, a second part 131, and a third part 132 are connected in series. The conductive material (e.g., nickel) included in the second part 131 may be different from the conductive material (e.g., copper) included in the first and third parts 130 and 132.

The separation distance (MG1) between an electrical connection structure closest to the lower die 120 among the plurality of electrical connection structures 130, 131, and 132 and the lower die 120 may be longer than the average separation distance (MG3) between the plurality of electrical connection structures 130, 131, and 132. Accordingly, when the plurality of electrical connection structures 130, 131, and 132 are formed, the possibility of the lower die 120 indirectly influencing (e.g., process dispersion factors) may be eliminated or reduced. A separation distance MG2 between the lower die 120 and the plurality of buffer dies 70 may or may not be formed according to design.

Referring to FIGS. 6B and 6C, a semiconductor package (PKG10, PKG11) according to some embodiments may further include a silicon dummy member 150 above the lower die 120 in a vertical direction and between the plurality of upper dies 60 in a horizontal direction. For example, the silicon dummy member 150 may be formed of silicon and may not include a device layer. For example, the silicon dummy member 150 may be provided so as to block the space between the at least four upper dies 60 of FIG. 1A, and may thus be in the form of a barrier having a +-shaped upper and lower surfaces. The width of the silicon dummy member 150 may be determined based on the horizontal size of the plurality of upper dies 60, and may help the semiconductor package (PKG10, PKG11) have a shape close to a rectangular parallelepiped. As seen in FIG. 6C, in a semiconductor package (PKG11) according to some embodiments, the plurality of upper dies 60 may not overlap with the lower die 120 in the vertical direction.

Referring to FIG. 6D, the semiconductor package (PKG12) according to some embodiments may have a structure in which bumps are omitted from the entirety of the plurality of upper dies 60 and the plurality of buffer dies 70, and may further include a bonding insulating layer (60D). The bonding insulating layer 60D may surround the pads 60P, 65P, and 70P, and may provide a bond between a plurality of upper dies 60 and a plurality of buffer dies 70, and a bond between memory dies of the plurality of respective upper dies 60. The combination structure of the bonding insulating layer 60D and the pads 60P, 65P, and 70P may be expressed as direct bonding, and may include a dielectric-to-dielectric bonding structure and a copper-to-copper bonding structure. For example, the bonding insulating layer 60D may include at least one of silicon oxide (SiO), silicon nitride (SiN), and silicon carbonitride (SiCN).

Depending on the design, the plurality of overlapped electrical connection structures 127 of FIG. 1B may also be replaced with the direct bonding structure or dielectric-to-dielectric bonding structure of FIG. 6D, and the overlap bumps 127C in FIG. 1B may also be omitted depending on the design.

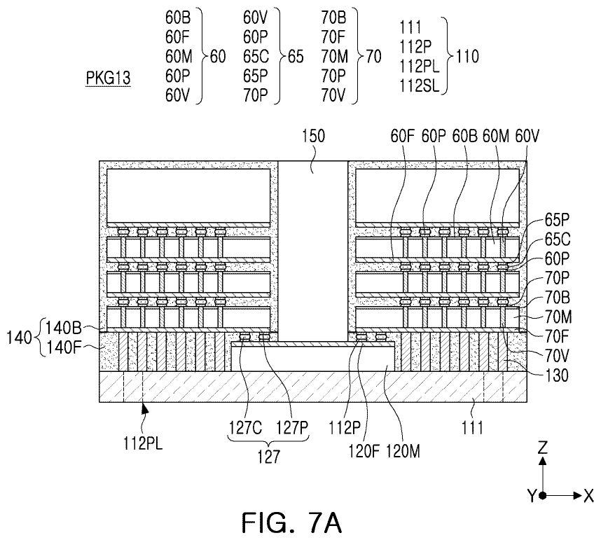

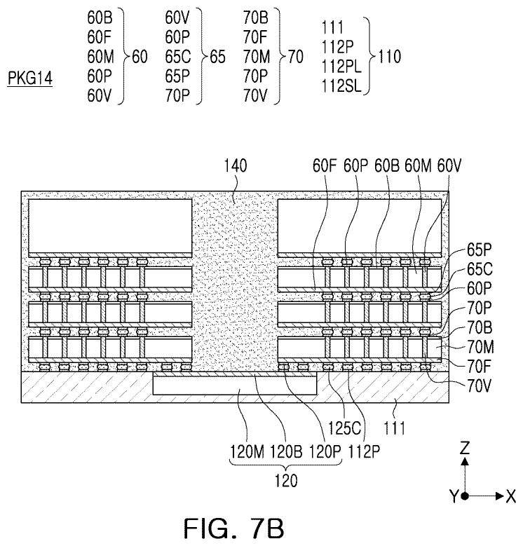

Referring to FIG. 7A, a semiconductor package (PKG13) according to some embodiments includes a plurality of overlapped electrical connection structures 127, and may have a structure that includes only one of the circuit layers 120B and 120F of the lower die 120 of FIG. 1B. The lower die 120 may not include through-vias, and may be electrically connected to a plurality of electrical connection structures 130 through a plurality of overlapped electrical connection structures 127 and buffer dies 70. Thus, in some embodiments, the structure of the lower die 120 is not limited to FIG. 1B.

Referring to FIG. 7B, at least a portion of the lower die 120 of the semiconductor package (PKG14) according to some embodiments may be embedded in a cavity in the package substrate 110. Accordingly, the plurality of electrical connection structures 125C may be shortened, and may be implemented more efficiently with bumps or solder balls.

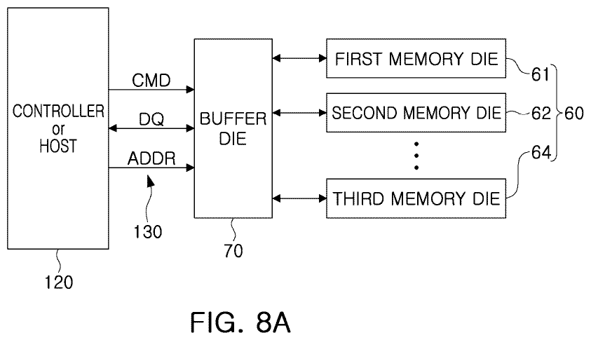

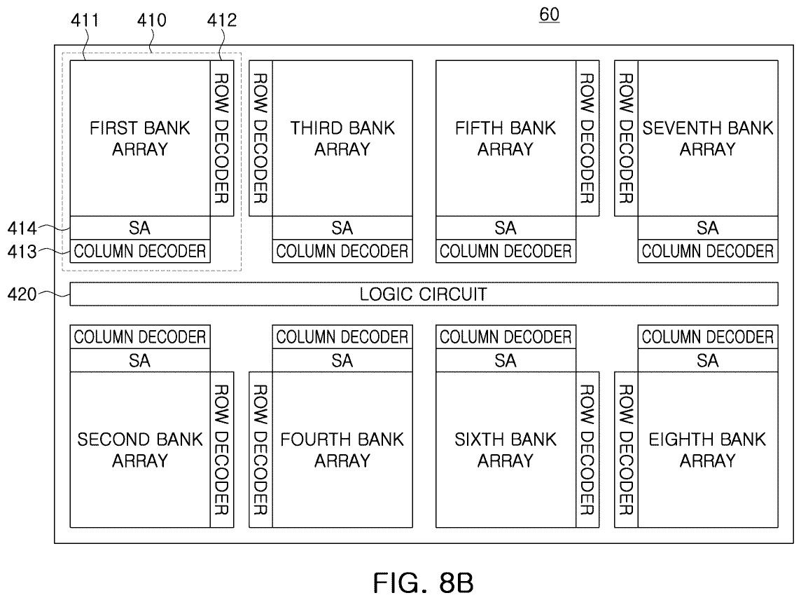

Referring to FIGS. 1A and 8A, the buffer die 70 may include an internal command generator 71, a via area 72, a physical (PHY) area 73, a direct access (DA) area 74, and an interface circuit 75. The internal command generator 71 may be configured to generate an internal command using a command signal (CMD) received from the lower die 120 or an external host.

The via area 72 may be an area where upper and lower electrical connection paths 65 for communication with the plurality of memory dies 61, 62, 63, and 64 are formed. The physical area 73 may be an area where input/output circuits for communication with the lower die 120 or an external host are placed. For example, a signal received from the lower die 120 or an external host may transmitted to the via area 72 through the physical area 73, and may be transmitted to at least one of the plurality of memory dies 61, 62, 63, and 64 through the upper and lower electrical connection paths 65.

The direct access area 74 may communicate (e.g., may communicate directly) with an external test device through a pad exposed to the outside of the semiconductor package PKG1 in a test mode for the semiconductor package PKG1. Signals provided from the test device may be provided to the plurality of memory dies 61, 62, 63, and 64 through the direct access area 74 and the via area 72. The interface circuit 75 may be configured to provide an address signal and a data signal provided from the lower die 120 or an external host to at least one target memory die among the plurality of memory dies 61, 62, 63, and 64, and the data signal output by the target memory die may be output to the lower die 120 or an external host. Additionally, the interface circuit 75 may be configured to provide a decision signal related to the test provided from the target memory die to an external device.

The lower die 120 may be a host or a controller in a memory device (or system). The interface of the host may be (UFS), but the present disclosure is not limited thereto. For example, the host Universal Flash Storage interface may be at least one of peripheral Component Interconnect Express (PCIe), Non-Volatile Memory Express (NVMe), Serial Attached SCSI (SAS), Small Computer System Interface (SCSI), SCSIe, Serial Advanced Technology Attachment (SATA), SATAe, Computer Express Link (CXL), and Gen-Z. The lower die 120 may be configured to provide a command signal (CMD), an address signal (ADDR), or the like used in the operation of the buffer die 70 and/or the plurality of memory dies 61, 62, 63, and 64 to the buffer die 70.

The buffer die 70 may be configured to buffer and transmit the command signal (CMD) and the address signal (ADDR) and transmit to at least one of the plurality of memory dies (61, 62, 63, and 64), and each of the plurality of memory dies 61, 62, 63, and 64 may be configured to execute control operations such as read, write, erase, and refresh, which may be performed in response to the command signal (CMD) and address signal (ADDR) received through the buffer die 70. The buffer die 70 and/or each of the plurality of memory dies 61, 62, 63, and 64 may also be configured to store queues. Accordingly, the buffer die 70 may perform control operations (example: data processing order determination operations, error and bad sector prevention operations, loading control operations, FBI (Frequency Boosting Interface) operations) for a plurality of memory dies 61, 62, 63 and 64.

The lower die 120 may be configured to receive the data signal DQ that is output as a result of the control operation of each of the plurality of memory dies 61, 62, 63, and 64 through the buffer die 70, and/or transmit a data signal (DQ) containing data to be stored through the buffer die 70.

FIG. 8B illustrates an internal block diagram based on a Dynamic Random Access Memory (DRAM) device of one memory die of each of the plurality of upper dies 60, but the present disclosure is not limited thereto. Referring to FIG. 8B, the memory die may include a plurality of memory banks 410 and a logic circuit 420. Each of the plurality of memory banks 410 may include a bank array 411 having a plurality of memory cells, a row decoder 412, a sense amplifier 413, and a column decoder 414.

A plurality of memory banks 410 included in the memory die may share one logic circuit 420. The logic circuit 420 may read data from the memory banks 410 and/or write data into the memory banks 410. Additionally, the logic circuit 420 may specify an address to store data and/or determine an operation mode of the memory die. Additionally, the logic circuit 420 may include an input/output circuit for transmitting data to be stored in a plurality of memory banks 410 and/or data output from the plurality of memory banks 410, and multiple pads connected to the input/output circuit.

A plurality of pads included in the logic circuit 420 may be connected to the plurality of via structures described above. A plurality of upper pads and a plurality of lower pads may be connected to both sides of the plurality of via structures, and the input/output circuit may receive signals from the memory die and the buffer die through a plurality of via structures, or may output a signal to the buffer die.

The bank array 411 may include a memory cell array having a plurality of memory cells. The row decoder 412 is connected to the memory cell array through a plurality of word lines, and the sense amplifier 413 may be connected to the memory cell array through a plurality of bit lines. A write operation that writes data to a plurality of memory cells, a read operation that reads data stored in a plurality of memory cells, or the like may be performed based on the command signal, address signal, or the like that are received by the logic circuit 420 from the buffer die.

As set forth above, the semiconductor package according to some embodiments may implement improved performance and/or increased capacity in an efficient manner. For example, in the semiconductor package, a number (or a total volume) of a plurality of upper dies may be efficiently increased, and design freedom/efficiency of a lower die may be improved. Accordingly, high performance and/or large capacity may be implemented relatively efficiently.

While some embodiments have been illustrated and described above, it will be apparent to those skilled in the art that modifications and variations could be made without departing from the scope of the present inventive concepts as defined by the appended claims.

What is claimed is:

1. A semiconductor package comprising:
a package substrate;
a plurality of upper dies on an upper side of the package substrate, each upper die arranged so as not to overlap vertically with other upper dies of the plurality of upper dies, and each upper die including a plurality of vertically overlapping memory dies;
a plurality of electrical connection structures between the package substrate and the plurality of upper dies, the plurality of electrical connection structures electrically connected to the package substrate;
a lower die on the package substrate and arranged so as not to vertically overlap with the plurality of electrical connection structures; and
a plurality of overlapped electrical connection structures arranged between an upper surface of the lower die and the plurality of upper dies, the plurality of overlapped electrical connection structures electrically connected to the upper surface of the lower die.

2. The semiconductor package of claim 1, wherein the plurality of upper dies includes at least four upper dies.

3. The semiconductor package of claim 2, wherein the at least four upper dies vertically overlap respective corners of the lower die.

4. The semiconductor package of claim 3, further comprising a plurality of buffer dies that are electrically connected between and to the plurality of upper dies and the plurality of electrical connection structures.

5. The semiconductor package of claim 4, wherein the plurality of electrical connection structures are arranged to at least partially surround the lower die, and
wherein lower surfaces of the plurality of buffer dies are located at a level coplanar with or above the upper surface of the lower die relative to an upper surface of the package substrate.

6. The semiconductor package of claim 1, wherein each of the plurality of upper dies partially overlaps the lower die vertically, and
wherein the plurality of electrical connection structures are asymmetrically arranged with respect to respective centers of the plurality of upper dies.

7. The semiconductor package of claim 6, wherein a separation distance between the lower die and an electrical connection structure closest to the lower die among the plurality of electrical connection structures is greater than an average separation distance between the plurality of electrical connection structures.

8. The semiconductor package of claim 1, further comprising a silicon dummy member provided vertically above the lower die and horizontally between the plurality of upper dies.

9. The semiconductor package of claim 1, wherein at least a portion of the lower die is embedded in the package substrate.

10. The semiconductor package of claim 1, further comprising a plurality of buffer dies that are electrically connected between and to the plurality of upper dies and the plurality of electrical connection structures.

11. The semiconductor package of claim 10, further comprising an encapsulant that seals the plurality of electrical connection structures and the lower die,
wherein lower surfaces of the plurality of buffer dies are in direct contact with the encapsulant.

12. The semiconductor package of claim 11, wherein the encapsulant comprises:
a lower encapsulant that seals the plurality of electrical connection structures and the lower die; and
an upper encapsulant that seals the plurality of upper dies,
wherein a lower surface of the upper encapsulant and an upper surface of the lower encapsulant have an interface therebetween.

13. The semiconductor package of claim 10, wherein first ones of the plurality of electrical connection structures are configured as signal paths between the plurality of upper dies and the lower die, and
second ones of the plurality of electrical connection structures other than the first ones are configured as power supply paths for the plurality of upper dies.

14. A semiconductor package comprising:
a package substrate;
a plurality of upper dies above the package substrate, each upper die arranged so as not to overlap vertically with others of the plurality of upper dies;
a plurality of electrical connection structures between the package substrate and the plurality of upper dies, the plurality of electrical connection structures electrically connected to the package substrate; and
a lower die on the package substrate and arranged so as not to overlap vertically with the plurality of electrical connection structures,
wherein each of the plurality of upper dies partially overlaps the lower die vertically, and
wherein the plurality of electrical connection structures are asymmetrically arranged with respect to respective centers of the plurality of upper dies.

15. The semiconductor package of claim 14, wherein the plurality of upper dies includes at least four upper dies
and wherein the at least four upper dies vertically overlap respective corners of the lower die.

16. The semiconductor package of claim 14, further comprising a plurality of buffer dies that are electrically connected between and to the plurality of upper dies and the plurality of electrical connection structures,
wherein each of the plurality of upper dies includes a plurality of memory dies overlapping each other vertically.

17. The semiconductor package of claim 14, wherein first ones of the plurality of electrical connection structures are used as signal paths between the plurality of upper dies and the lower die, and
second ones of the plurality of electrical connection structures are used as power supply paths for the plurality of upper dies.

18. A semiconductor package comprising:
a package substrate;
at least one upper die on the package substrate;
a plurality of electrical connection structures between the package substrate and the at least one upper die, the plurality of electrical connection structures electrically connected to the package substrate;
a lower die on the package substrate and arranged so as not to vertically overlap with the plurality of electrical connection structures;
an encapsulant that seals the plurality of electrical connection structures and the lower die; and
at least one buffer die electrically connected between and to the at least one upper die and the plurality of electrical connection structures,
wherein a lower surface of the buffer die is in direct contact with the encapsulant.

19. The semiconductor package of claim 18, wherein the encapsulant comprises:
a lower encapsulant that seals the plurality of electrical connection structures and the lower die; and
an upper encapsulant that seals the at least one upper die,
wherein an interface is between a lower surface of the upper encapsulant and an upper surface of the lower encapsulant. 20 The semiconductor package of claim 19, wherein the at least one upper die includes at least four upper dies which are arranged so as not to overlap each other vertically.
wherein the at least four upper dies vertically overlap respective corners of the lower die.
